(19) United States
(12) Patent Application Publication
(10) Pub. No.: US 2014/0043907 A1
(43) Pub. Date: Feb. 13, 2014

(54) NONVOLATILE MEMORY DEVICE AND METHOD FOR VOLTAGE TRIMMING THEREOF

(71) Applicant: KABUSHIKI KAISHA TOSHIBA, Tokyo (JP)

(72) Inventor: Susumu FUJIMURA, Kanagawa (JP)

(73) Assignee: Kabushiki Kaisha Toshiba, Tokyo (JP)

(21) Appl. No.: 13/782,991

(22) Filed: Mar. 1, 2013

(30) Foreign Application Priority Data
Aug. 8, 2012 (JP) 2012-176541

(51) Int. Cl. G11C 16/26

(52) U.S. Cl. CPC G11C 16/26
USPC 365/185.11

(57) ABSTRACT

A non-volatile semiconductor storage device includes memory blocks that each includes multiple memory strings. A bit line connects to an end of each string in the memory blocks and to a sense amplifier circuit which includes a first transistor. The device includes first and second discharge transistors for discharging the bit line. The first discharge transistor is located further, in the bit line direction, from the sense amplifier circuit than the second discharge transistor. The sense amplifier provides a sensing voltage to the bit line for reading data in the memory strings. A control circuit controls the level of the sensing voltage by supplying a trimming voltage to a gate of the first transistor in the sense amplifier to thereby adjust the level of the sensing voltage according to the distance of a selected memory block from sense amplifier to compensate for changes in the bit line resistance.

### CROSS-REFERENCE TO RELATED APPLICATION

This application is based upon and claims the benefit of priority from Japanese Patent Application No. 2012-176541, filed Aug. 8, 2012, the entire contents of which are incorporated herein by reference.

### FIELD

Embodiments described herein relate to a nonvolatile memory device and a NAND-type flash memory.

### BACKGROUND

The NAND-type flash memory includes a memory string with serially connected memory cells in an array along a column direction, and each memory string is connected to a corresponding bit line via a selection gate transistor. Each bit line connects to a sense amplifier circuit that senses the data stored in the memory cells. All of the memory cells that are arrayed along a row direction (across a common word line) are selected at the same time, and bulk write or read action may be conducted on all of these memory cells that are selected at the same time.

With the miniaturization of NAND-type flash memory devices, the interconnection resistance of the bit line has increased. As a result, the bit line voltage that is applied to the selected memory cell may greatly differ according to the distance from the sense amplifier. This increase in the interconnection resistance of the bit line voltage also increases the possibility for data read errors.

### DESCRIPTION OF THE DRAWINGS

FIG. 1 is a block diagram that shows an example of a memory device according to an embodiment.

FIG. 2 is a circuit diagram that shows an example of a memory cell array according to an embodiment.

FIG. 3 is a circuit diagram that shows an example of a memory block according to an embodiment.

FIG. 4 is a circuit diagram that shows an example of a sense amplifier.

FIG. 5 is a block diagram that shows an example of a zone.

FIG. 6A and FIG. 6B are cross-section diagrams that show an example of a memory cell and a select transistor, respectively.

FIG. 7 is a cross-section diagram that shows a cross-section of a NAND-type flash memory.

FIG. 8 is a depicting voltages supplied to each device region shown in FIGS. 6A and 6B.

FIG. 9 is a diagram showing a threshold distribution of the memory cell in the case of storing 8-value data.

FIG. 10 is a flowchart depicting the process of determining a set value of a clamp voltage in a first embodiment.

FIG. 11 is a diagram showing one example of a current path in a first step in the first embodiment.

FIG. 12 is a diagram showing one example of a current path in a second step in the first embodiment.

FIG. 13 is a circuit diagram that shows a driver control circuit of a source line driver.

FIG. 14 is a circuit diagram that shows a bit line current detection circuit.

FIG. 15 is a flowchart depicting the process of determining the set value of the clamp voltage in a second embodiment.

FIG. 16 is a diagram showing one example of a current path in a first step in the second embodiment.

FIG. 17 is a diagram showing one example of the current path in the second step in the second embodiment.

FIG. 18 is a block diagram that depicts a trimming block in a variant of the second embodiment.

### DETAILED DESCRIPTION

The present disclosure describes highly reliable, nonvolatile memory devices. In general, embodiments are described with reference to the drawings.

According to an embodiment, a non-volatile semiconductor storage device includes a plurality of memory blocks, each memory block including a plurality of memory strings, a bit line extending in a first direction (the bit line direction) and connected to an end of a memory string in each memory block. The device further includes a first discharge transistor connected to the bit line proximate to a first end of the bit line and a second discharge transistor connected to the bit line proximate to a second end of the bit line that is separated from the first end in the first direction by two or more memory blocks. A sense amplifier is connected to the bit line at the second end. The sense amplifier is configured to provide a sensing voltage to the bit line for reading data in the memory strings. A control circuit that is configured to control the sensing voltage by supplying a trimming voltage to a gate of a first transistor in the sense amplifier adjusts the trimming voltage based on a distance in the bit line direction of a selected memory block from the sense amplifier.

Another embodiment of the semiconductor storage device is characterized by being equipped with multiple blocks, each of which includes multiple memory cells; multiple bit lines that are each connected to one end of the multiple memory cells that are assigned to each of the multiple blocks and extend in the first direction; multiple sense amplifier circuits, each of which includes a first transistor, and the first transistors are connected to one end of the multiple bit lines; multiple second transistors that are each assigned to locations (zones) that are near the sense amplifier circuits of the multiple bit lines and are each connected to the multiple bit lines; multiple third transistors that are each assigned to locations (zones) that are far from the sense amplifier circuits of the multiple bit lines and are each connected to the multiple bit lines; source lines that are assigned to each of the multiple blocks and commonly connect to the other ends of the multiple memory cells; and a control circuit, which the control circuit changing the voltage that is applied to the control line of the multiple first transistors, according to the position of the select blocks that have assigned to them the multiple memory cells that have been selected from the multiple blocks, based on the trimming voltage that makes the control line make the currents that pass through the multiple second transistors and the multiple third transistors the same when applying a first voltage to the bit lines.

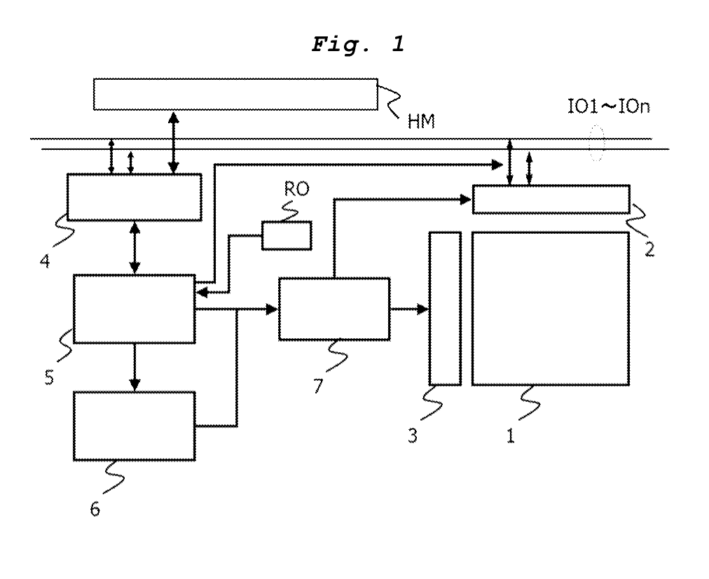

First, as shown in FIG. 1 through FIG. 3, the memory device according to a first embodiment is described using the configuration of a NAND-type flash memory as an example.

The NAND-type flash memory is equipped with a memory cell array 1 that is composed of a memory cell MC that stores data. This memory cell array 1 includes multiple bit lines BL, multiple word lines WL, a common source line CELSRC, and multiple memory cells MC. The memory cell MC can store n-bits (n is a natural number equal to or greater than 1) of data in one memory cell.

The various commands CMD, addresses ADD, and data DT that control the operation of the NAND-type flash memory are provided from the host or the memory controller HM and input into a buffer 4. The write data that are input into the buffer 4 are provided to the bit line BL that is selected by the bit line control circuit 2 via the data input-output lines IO1-IOn (where n is natural number). Furthermore, the various commands CMD and addresses ADD are input into a control circuit 5, and the control circuit 5 controls a booster circuit 6 and a driver 7 based on the commands CMD and addresses ADD.

The booster circuit 6 generates the voltages necessary for the write, read, and erase operations and provides these voltages to the driver 7. The driver 7 provides these voltages to the bit line control circuit 2 and the word line control circuit 3. The bit line control circuit 2 and the word line control circuit 3, with these voltages, read data from the memory cells MC, write data to the memory cells MC, and erase data from the memory cells MC.

The memory cell array 1 are connected to the bit line control circuit 2 that controls the voltage of the bit line BL and the word line control circuit 3 that controls the voltage of the word line WL. Furthermore, the bit line control circuit 2 and the word line control circuit 3 are connected to the driver 7.

Specifically, the driver 7 controls the bit line control circuit 2 based on the address ADD and reads the data from the memory cell MC in the memory cell array 1 via the bit line BL. Furthermore, the driver 7 controls the bit line control circuit 2 based on the address ADD and writes the data to the memory cell MC in the memory cell array 1 via the bit line BL.

The memory device includes a ROM region RO. The ROM region RO can store a trimming voltage value, which is described below. The control circuit 5 reads the trimming voltage value from the ROM region RO and can control the bit line control circuit 2, the booster circuit 6, and the driver 7 accordingly. Here, the circuit element that is arranged in the ROM region RO can have the same composition as the memory cell MC that is arranged in the memory cell array 1. Furthermore, the ROM region RO can be arranged in the memory cell array 1.

Additionally, the bit line control circuit 2, the word line control circuit 3, the driver 7, and the control circuit 5 can be collectively called the “control circuit.”

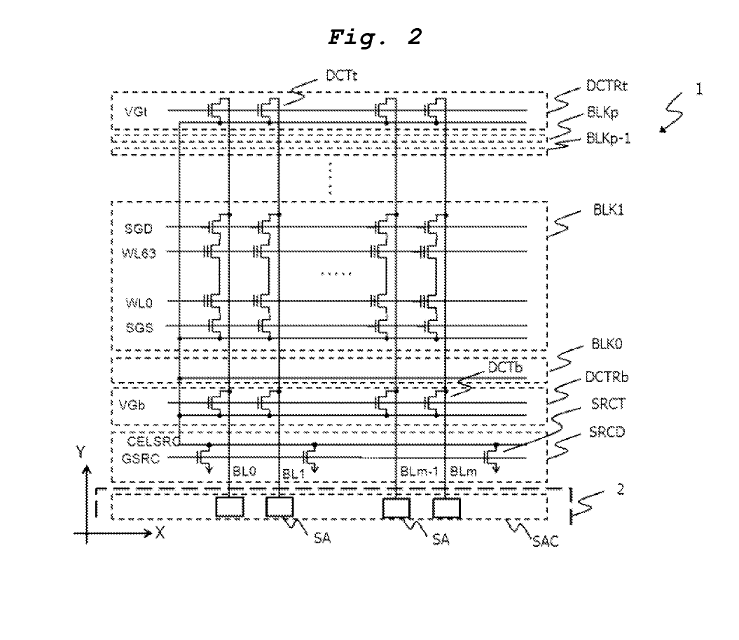

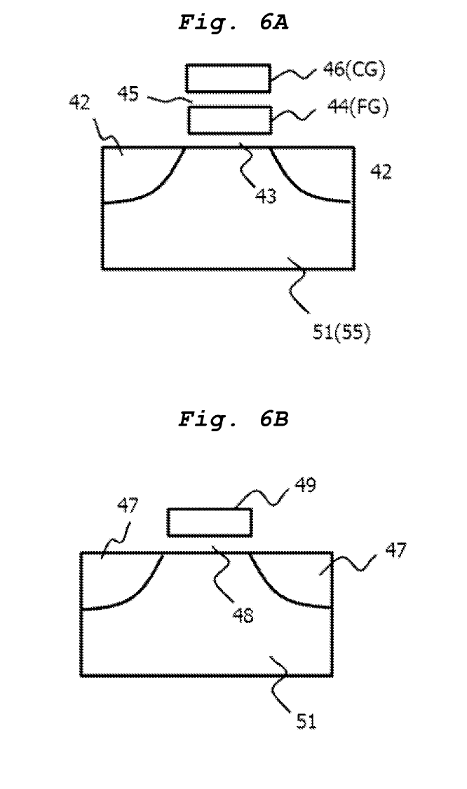

FIG. 2 shows one example of a circuit configuration of the memory cell array 1 shown in FIG. 1. The memory cell array 1 includes multiple blocks BLK0 to BLKp (p is an integer number greater than or equal to 0) and discharge circuits DCTRb and DCTRt. These elements are arranged on the same cell well 55 (see FIGS. 6A and 6B).

In the Y-direction, multiple blocks BLK0 to BLKp are arranged from the sense amplifier group SAC side that is arranged in the bit line control circuit 2, as block BLK0, block BLK1 . . . block BLKp−1, and BLKp. In the Y-direction is arranged a discharge circuit DCTRb in between the sense amplifier circuit group SAC and the block BLK0. In the Y-direction is also arranged a discharge circuit DCTRt on the side of the block BLKp that is farther from the sense amplifier group SAC.

That is, in the Y-direction, the discharge circuit DCTRb can be arranged in between the block BLK0 that is closest to the sense amplifier circuit group SAC and the sense amplifier circuit group SAC, and the discharge circuit DCTRt can be arranged beyond the block BLKp that is farthest from the sense amplifier circuit group SAC.

Meanwhile, in the Y-direction, the other blocks BLK can be arranged in between the discharge circuit DCTRt and the sense amplifier circuit group SAC. Also, in the Y-direction, the blocks BLK can be arranged beyond the discharge circuit DCTRt. That is, in the Y-direction, the discharge circuit DCTRb just needs to be arranged closer to the sense amplifier circuit group SAC than the discharge circuit DCTRt and need not necessarily be at an edge of the memory array 1.

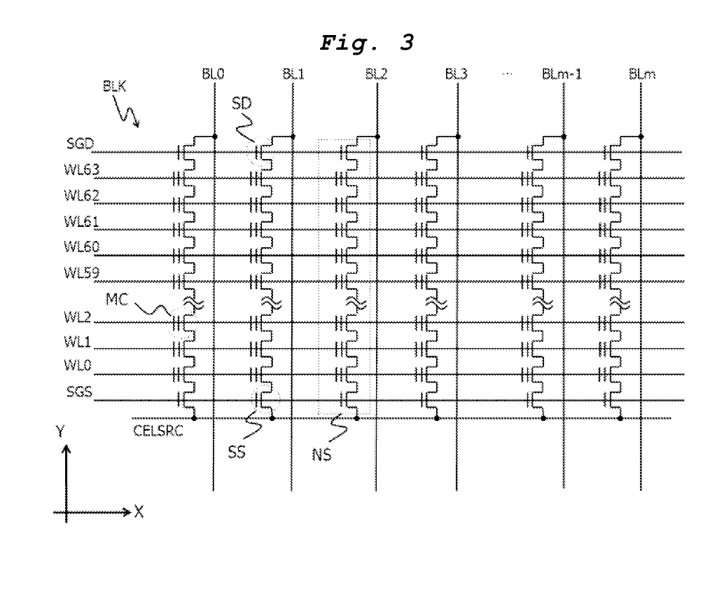

FIG. 3 shows one example of the circuit configuration of a block BLK shown in FIG. 2. Multiple NAND strings NS are arranged in the block BLK. One NAND string NS includes a memory string that includes, for example, 64 memory cells MC that are series-connected in the Y-direction (i.e., the bit line direction) and select transistors SD and SS that are connected to the two ends of the memory cell string. Additionally, dummy memory cells can be arranged in between the memory string and the select transistor SD or between the memory string and the select transistor SS. Also, the number of memory cells MC is not limited to 64.

Multiple NAND strings NS (m+1 in the example in FIG. 2) are arranged in the X-direction (i.e., word line direction), one of the bit lines BL is connected to one end of the NAND string NS, and the common source line CELSRC is connected to the other end. That is, multiple NAND strings NS are arranged in the Y-direction, one of the multiple bit lines is connected to one end of the NAND string NS, and a common source line CELSRC is connected to the other end. The gate electrode of the select transistors SD and SS are each connected to the selection transistor control lines SGD and SGS, respectively.

The word lines WL extends in the word line direction (X direction) and makes a common connection with the memory cells MC that are aligned in the word line direction. One page includes the memory cells MC that are connected in the word line direction. The write operation to the memory cell MC is carried out in pages. But note, it is important to point out that the “page” that is the unit of the write operation is a different concept from the “lower page” and “upper page,” which are data write bit levels, as described below. Furthermore, the erase operation on the memory cell is carried out in blocks.

As shown in FIG. 2, bit lines are shared across multiple blocks BLK. That is, bit lines are shared by NAND strings NS that are next to each other in the Y-direction in the multiple blocks BLK.

Furthermore, as shown in FIG. 2, a discharge circuit DCTRb and a discharge circuit DCTRt both include multiple discharge transistors DCTb and DCTt arrayed in the word line direction (x-direction). The discharge transistors DCTb and DCTt are, for example, n-type MOS transistors. One end of each discharge transistor DCTb and DCTt is connected to the bit line BL, and the other end is connected to the common source line CELSRC. That is, the discharge transistor DCTb is connected to the bit line BL that is between the sense amplifier circuit group SAC and the block BLK0, and the discharge transistors DCTt is connected to the bit line BL beyond the block BLKp (on the side that is farther from the sense amplifier circuit group SAC in the Y-direction). Furthermore, each bit line BL is connected to the common source line CELSRC via the discharge transistors DCTb and DCTt.

The gate electrodes (control line) of the discharge transistor DCTb are commonly connected with a wire VGb. The gate electrodes (control line) of the discharge transistor DCTt are commonly connected with the wire VGt. Here, by controlling the wires VGb and VGt, the control circuit 5 can discharge the bit line to the common source line CELSRC via the discharge transistors DCTb and DCTt. For example, after the readout process as described below, the control circuit 5 can discharge the bit line and reset the potential of the bit line BL. Furthermore, in the Y-direction, with the discharge circuits DCTRb and DCTRt being arranged in a position that is close to and a position that is far from the sense amplifier circuit group SAC, the potential of the bit line BL can be rapidly discharged.

Additionally, the source line driver SRCD is positioned between the sense amplifier circuit group SAC and the discharge circuit DCTRb. Meanwhile, the source line driver SRCD may be positioned beyond the discharge circuit DCTRt.

The source line driver SRCD includes multiple source driver transistors SRCT. One end of each of the multiple source driver transistors SRCT is connected to the common source line CELSRC and the other end is connected to an electrical supply circuit or a ground voltage. In the present example, an example in which the source driver transistor SRCT is an n-type MOS transistor and the other end is connected to the ground voltage will be described. The gate electrode (control line) of each source driver transistor SRCT makes a common connection with the wire GSRC. The control circuit 5 can adjust the potential of the common source line CELSRC using the source line driver SRCD. For example, the control circuit 5 can control the voltage that is applied to the wire GSRC, thereby controlling the ON/OFF function of the source driver transistor SRCT. Only one source driver transistor SRCT is required.

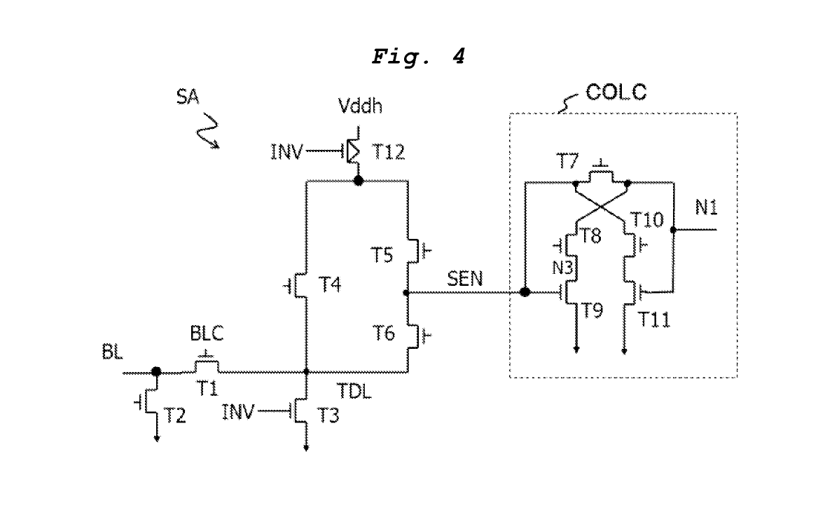

FIG. 4 shows an example circuit diagram of a sense amplifier SA that is positioned in the sense amplifier circuit group SAC. As depicted in FIG. 4, the sense amplifier includes twelve transistors T1 to T12. Here, the transistors T1 to T11 are n-type transistors, and the transistor T12 is a p-type transistor. The bit line BL is connected to one end of the transistor T1 and transistor T2. The other end of the transistor T1 is connected to the node TDL. Furthermore, the control circuit 5 can apply the clamp voltage BLC to the gate electrode (control line) of the transistor T1. The other end of the transistor T2 is connected to the power-supply voltage. Connected to the node TDL is one end of each of the transistors T3, T4, and T6. The other end of the transistor T3 is connected to the power-supply voltage. The other end of the transistor T6 is connected to the node SEN. The other end of the transistor T5 is also connected to the node SEN. One end of the transistor T12 is connected to the power-supply voltage Vddh, and the other end is connected to the other end of the transistor T4 and the other end of the transistor T5. Also, the gate electrode (control line) of the transistor T3 and the gate electrode (control line) of the transistor T12 are connected to the signal INV. That is, the transistor T3 and the transistor T12 are in a relationship in which, when one is ON, the other is OFF.

The node SEN is connected to the control line of the transistor T9 and to one end of each of the transistors T7 and T10. One end of the transistor T9 is connected to the ground voltage. The node N3 is connected to the other end of the transistor T9.

Also, the node N1 is connected to the control line of the transistor T11. One end of the transistor T11 is connected to the other end of the transistor T10, and the other end of the transistor T11 is connected to the ground voltage.

Here, the transistors T7 to T11 are included in the arithmetic circuit COLC. The arithmetic circuit COLC can conduct a NOT operation on the node SEN signal and the node N1 signal, as well as an AND operation on the node SEN signal and the node N1 signal (i.e., the data that are handed off to the data latch group).

The sense operation of the sense amplifier SA is described in the following. First, the control circuit 5 turns the transistors T1, T4, and T12 ON. As a result, the bit line BL is boosted to the pre-charge voltage. At this time, the control circuit 5 can adjust the clamp voltage BLC that is applied to the gate electrode of the transistor T1. That is, in the case that the memory cell MC being addressed is in a position far from the sense amplifier SA (sense amplifier circuit group SAC), the control circuit 5 increases the clamp voltage BLC and increases the voltage that is applied to the bit line. On the other hand, in the case that the addressed memory cell MC that is near the sense amplifier (sense amplifier circuit group SAC), the control circuit 5 decreases the clamp voltage BLC and decreases the voltage that is applied to the bit line. That is, regardless of the position of the selected memory cell MC, the bit line voltage that is applied to the selected memory cell MC (or the selected NAND string NS, or the selected block BLK) can be made roughly constant by accounting for bit line resistance.

The multiple blocks arranged in the memory cell array 1 can be divided into zones and managed so that control circuit 5 can control them more easily. For example, the clamp voltage BLC that is used when the selected memory cell MC belongs to each zone can be set in advance (and stored in, for example, ROM region RO). Here, the control circuit 5 controls the potential of the bit line based on which zone the selected memory cell MC belongs.

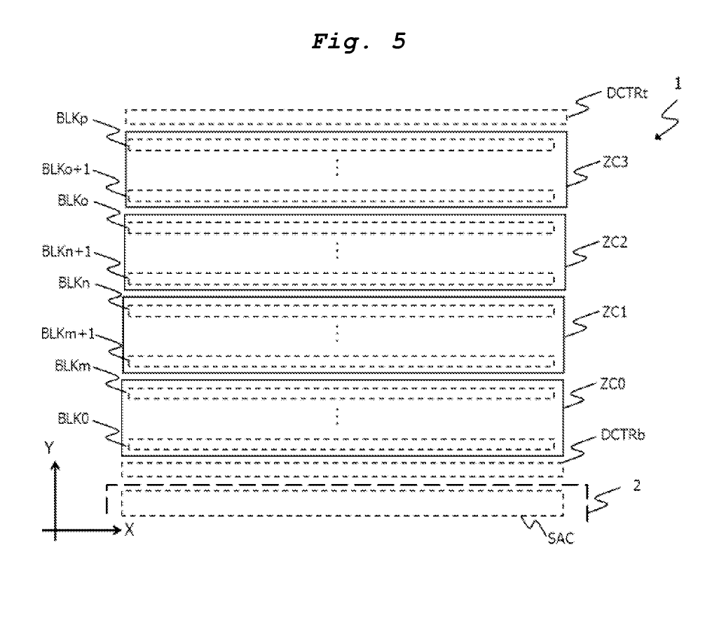

For example, as shown in FIG. 5, in the Y-direction, from the closest to the sense amplifier circuit group SAC, zone ZC0, zone ZC1, zone ZC2, and zone ZC3 are set, in that order. That is, the memory cell array 1 is divided into four zones. Of course, the number of zones is not limited to four. The memory cell array 1 need only be divided into at least two zones.

In zone ZC0, blocks BLK0 to BLKm are arranged. In zone ZC1, blocks BLKm+1 to BLKn are arranged. In zone ZC2, blocks BLKn+1 to BLKo are arranged. In zone ZC3, blocks BLKo+1 to BLKp are arranged. Here, m, n, o, and p are natural numbers greater than or equal to 2 and have the relationship m<n<o<p. The number of blocks BLK that are arranged in each zone ZC can be different, that is the zones need not have equal sizes.

Here, in the case that the memory cell MC arranged in zone ZC0 is selected (henceforth, this can be referred to as “selecting zone ZC”), the control circuit 5 turns the transistor T1 ON, using the 0th clamp voltage BLC0. At the same time, the control circuit 5 turns the transistor T1 ON using the first clamp voltage BLC1 in the case that zone ZC1 is selected, the second clamp voltage BLC2 in the case that zone ZC2 is selected, and the third clamp voltage BLC3 in the case that zone ZC3 is selected. Here, the relationship is such that the 0th clamp voltage BLC0<first clamp voltage BLC1<second clamp voltage BLC2<third clamp voltage BLC3. Also, each clamp voltage BLC can be set by raising the clamp voltage by a set incremental value for each successive zone. For example, the trimming voltage is made the voltage DACtum (corresponding to the fourth trimming voltage described below). The control circuit 5 turns the transistor T1 ON using the 0th clamp voltage BLC0 in the case that zone ZC0 is selected, the 0th clamp voltage BLC0+DACtum in the case that zone ZC1 is selected, the 0th clamp voltage BLC0+2×DACtum in the case that zone ZC2 is selected, and the 0th clamp voltage BLC0+3×DACtum in the case that zone ZC3 is selected.

In this way, by controlling by zones ZC, the bit line voltage that is actually applied to the selected memory cell MC (or the selected NAND string NS) can be made roughly constant, regardless of the position of the selected memory cell MC in the memory array.

Next, the control circuit 5 turns the transistor T5 ON. As a result, the node SEN is pre-charged. Then, the control circuit 5 turns the transistor T6 ON.

At this time, in the case that the memory cell MC is storing the data “1,” the bit line BL is discharged. An example is the case in which the threshold voltage of the memory cell MC is lower than the read voltage, the verify voltage, etc. As a result, the node SEN is lowered to the L level. After that, the transistor T6 is closed, and data is retained in the node SEN. Meanwhile, when the transistor T6 is closed, the transistors T7, T8, and T10 are also OFF.

On the other hand, in the case that the memory cell MC is storing the data “0,” the bit line BL is not discharged. An example is the case in which the threshold voltage of the memory cell MC is higher than the read voltage, verify voltage, etc.

After that, the transistor T6 is closed, and data is retained at the node SEN. Meanwhile, when the transistor T6 is closed, the transistors T7, T8, and T10 are also OFF.

The control circuit 5, by controlling the transistors T7 to T11, can conduct the data hand-off between the node SEN and the node N1, as well as the operations of the node SEN and the node N1.

Thus, with the control circuit 5 controlling the clamp voltage BLC, data read error that accompanies the increase in the interconnection resistance of the bit line can be prevented.

FIG. 6A and FIG. 6B show the cross-section diagram of the memory cell and the select transistor. FIG. 6A shows the memory cell. On a substrate 51 (cell well 55 is described below) are formed an n-type diffusion layer 42 as the source and drain of the memory cell. On the p-type well region (cell well 55) is formed a charge accumulation layer (FG) 44 via a gate insulating film 43, and on this charge accumulation layer 44 is formed a control gate (CG) 46 via an insulating film 45. FIG. 6B shows the select gate. On the cell well 55 is formed an n-type diffusion layer 47 as the source and drain. On the cell well 55 is formed a control gate 49 via the gate insulating film 48.

By accumulating charge in the charge accumulation layer (FG), the threshold voltage of the memory cell can be changed. By allocating data according to this threshold voltage, data can be stored. Normally, multiple memory cells are used to store data. As a result, the threshold value of the memory cell forms a threshold distribution that corresponds with each data set value.

FIG. 7 shows one example of a cross-section diagram of the NAND-type flash memory. For example, in the P-type memory device 51 are formed N-type well regions 52, 53, and 54 and a P-type well region 56. In the N-type well region 52 is formed the cell well 55, and in this cell well 55 is formed a memory cell Tr that includes the memory cell array 1. Furthermore, in the N-type well region 53 and the P-type well region 56 are formed, for example, a low-voltage P-channel transistor LVPTr and a low-voltage N-channel transistor LVNTr that include the control circuit 5. On the substrate 51 is formed, for example, a high-voltage N-channel transistor HVNTr that connects the word line and the world line control circuit 3. Furthermore, in the N-type well region 54 is formed, for example, a high-voltage P-channel transistor HVPTr that includes the word line control circuit 3. As shown in FIG. 5, the high-voltage transistors HVNTr and HVPTr include gate insulating film that are, for example, thicker than those of the low-voltage transistors LVNTr and LVPTr.

Meanwhile, the discharge transistors DCTd and DCTt can be positioned on the cell well 55. Also, the source driver transistor SRCT can be positioned on the P-type well region 56, etc.

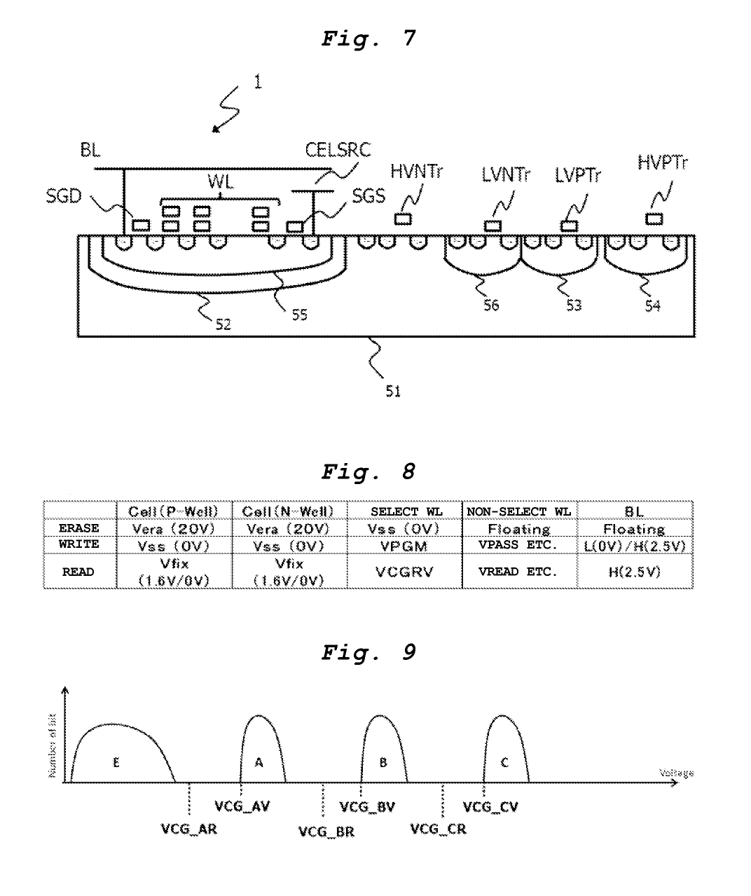

FIG. 8 shows an example of voltages that are supplied to each region shown in FIG. 7. In the erase operation, the program operation, and the read operation, voltages are provided to each region as shown in FIG. 8. Here, Vera is the voltage that is applied to the substrate at the time of data erase; Vss is the ground voltage; Vdd is the power-supply voltage; the write voltage Vpgm is the voltage that is provided to the select word line at the time of data write; the read voltage Vcgrv is the variable voltage that is provided to the select word line at the time of the data read operation; the read pass voltage Vread is the voltage that is supplied to the selected word line at the time of the data read operation; and the write pass voltage Vpass is the voltage that is supplied to the non-select word line at the time of the data write operation.

### (Threshold Distribution of the Memory Cell)

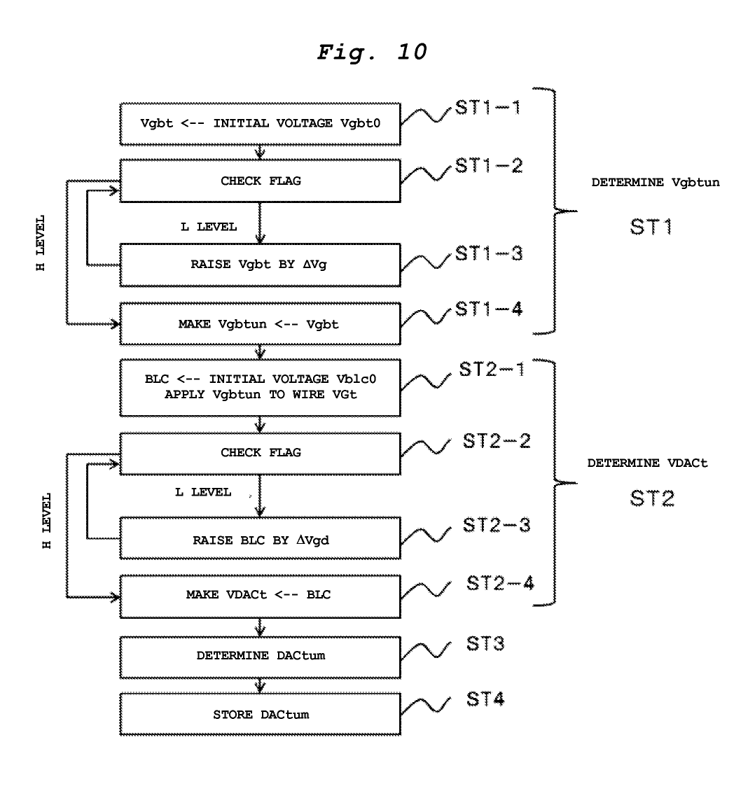

The threshold distribution of the memory cells and the storage of data will be described using FIG. 9. FIG. 9 is a diagram showing one example of the threshold distribution of the memory cells MC in the case that the NAND-type flash memory, for example, stores 4-value data.

For example, in the case that one memory cell MC stores 2 bits, as shown in FIG. 9, the threshold value of the multiple memory cells MC includes four threshold distributions. Here, in the order of low to high threshold voltage, they shall be called the “E” distribution (erase state), “A” distribution, “B” distribution, and “C” distribution. Here, from the left in order, if they are the upper data and lower data, the 2-bit data can be assigned to the threshold distributions as follows. For example, “11” data can be assigned to the “E” distribution, “01” data to the “A” distribution, “00” data to the “B” distribution, and “10” data to the “C” distribution.

### (Write Operation)

The data write operation of the NAND-type flash memory will be described in the following. The write operation includes a program operation that applies the write voltage and a verify operation that checks the threshold voltage of the memory cell after the program operation. Meanwhile, the verify operation does not necessarily have to be carried out after the program operation, and various changes, such as those being carried out once every several program operations, etc., are possible.

With the write operation, the booster circuit 6 and the control circuit 5 apply the write voltage VPGM to the selected word line WL (henceforth may be called “select word line WLs”); the booster circuit 6 and control circuit 5 also apply the pass voltage VPASS, etc., to the word lines other than the select word line WLs that are not selected (henceforth may be called “non-select word line WLns”). Meanwhile, the pass voltage VPASS is not limited to cases in which the same voltage is applied at all the non-select word lines WLns; the pass voltage VPASS can be different between the non-select word lines WLns.

Meanwhile, in each NAND string NS, data is often written to the memory cell MC from the common source line CELSRC side.

In the case that the threshold voltage of the memory cell MC that is connected to the select word line WLs is to be raised, the bit line control circuit 2 sets the voltage of the bit line BL to, for example, 0V. As a result, the potential difference between the select word line WLs and the channel of the memory cell MC increases, and charge is injected into the charge accumulation layer FG. In the case that the threshold voltage of the memory cell MC connected to the select word line WLs is not to be raised, the bit line control circuit 2 sets the voltage of the bit line BL to, for example, 2.5V. As a result, the channel of the memory cell MC rises due to the so-called self boost. The potential difference between the selected word line WLs and the channel of the memory cell MC decreases, and charge is hardly injected into the charge accumulation layer FG.

The verify operation is carried out by the control circuit 5 selecting the select word line WLs and applying the verify voltage VCGVV to the select word line WLs. In other words, one page is selected. A pass voltage VREAD that turns the memory cell MC ON is applied to the non-select word line WLns besides the select word line WLs is, irrespective of the threshold voltage of the memory cell MC. The pass voltage VREAD is not limited to cases in which the same voltage is applied to all of the non-select word lines WLns; the pass voltage VREAD can be different between the non-select word lines WLns.

Here, after 0V is applied to the common source line CELSRC and the pre-charge voltage to the bit line BL, the select transistors SD and SS are turned ON. If the threshold voltage of the memory cell MC is higher than the verify voltage, the voltage that is charged in the bit line BL is not discharged. This result is sensed and latched at the sense amplifier, and the data of the memory cell is determined to be “0” data. On the other hand, if the threshold voltage of the memory cell MC is lower than the verify voltage, the voltage that is charged in the bit line is discharged. This result is sensed and latched at the sense amplifier, and the data of the memory cell MC is determined to be “1” data.

The control circuit 5, by changing the verify voltage to the verify voltage VCG_AV, VCG_BV, and VCG_CV, determines whether or not the select memory cell MC is written to the set threshold voltage.

Meanwhile, 0V (in some cases a positive voltage) can be applied to the cell well 55 of the memory cell. In the case that the set threshold voltage has not been written on the memory cell MC, the write voltage VPGM is stepped up, and the write operation is carried out once more.

### (Read Operation)

The data read operation of the NAND-type flash memory will be described in the following. The control circuit 5 selects one select word line WLs from the multiple word lines WL and applies the read voltage Vcgrv to the select word line WLs. In other words, one page is selected. A pass voltage Vread that turns the memory cell MC ON is applied to the non-select select word line WLns besides the select word line WLs is, irrespective of the threshold voltage of the memory cell MC. This pass voltage Vread is not limited to cases in which the same voltage is applied to all of the non-select word lines WLns; the pass voltage Vread can be different between the non-select word lines WLns. Here, after 0V is applied to the common source line and the pre-charge voltage to the bit line BL, the select transistors SD and SS are turned ON. If the threshold voltage of the memory cell MC is higher than the verify voltage, the voltage that is charged to the bit line BL is not discharged. The potential of this bit line BL is detected by the sense amplifier S/A, and the data of the memory cell MC is determined to be “0” data. On the other hand, if the threshold voltage of the memory cell MC is lower than the verify voltage, the voltage that is charged in the bit line is discharged. The potential of this bit line BL is detected by the sense amplifier S/A, and the data of the memory cell MC is determined to be “1” data. Meanwhile, 0V (in some cases a positive voltage) can be applied to the cell well 55 of the memory cell.

The read voltage Vcgrv differs depending on the page that is read (here, meaning “upper page”, etc.). In the example shown in FIG. 9, the read voltage Vcgrv is set in between the threshold distribution of each. For example, the read voltage VCG_AR is set in between the “E” distribution and the “A” distribution, the read voltage VCG_BR is set in between the “A” distribution and the “B” distribution, and the read voltage VCG_CR is set in between the “B” distribution and the “C” distribution.

### (Erase Operation)

The erase operation is, for example, carried out in blocks. The control circuit 5 applies the voltages shown in “erase” in FIG. 8. As a result, the potential difference between the select word line WLs and the channel of the memory cell MC increases, and the charge that is accumulated in the charge accumulation layer FG is pulled out to the p-type well region. In the case that the data of the memory cell is not to be erased, the word line is made non-select, and the non-select word line WLns is put in a floating state. As a result, the potential of the non-select word line WLns rises by the boost effect, as well as the potential difference between the non-select word line WLns and the channel of the memory cell MC. Therefore, the charge that is accumulated in the charge accumulation layer FG is hardly pulled out to the p-type well region. After the erase operation, the threshold voltage of all of the memory cells MC in the block becomes the “E” distribution in FIG. 9.

### First Embodiment

The NAND-type flash memory is miniaturized to cut manufacturing costs. As a result, the wiring width of the bit line decreases, and the interconnection resistance of the bit line increase. Also, if the wiring width of the bit line BL decreases, the effects of the variability in the manufacture processing increase. Thus, if the control value of the clamp voltage BLC is uniformly set, cases will arise in which the adjustment of the clamp voltage BLC is insufficient. An example is cases in which the interconnection resistance of the bit line is different for each chip, etc.

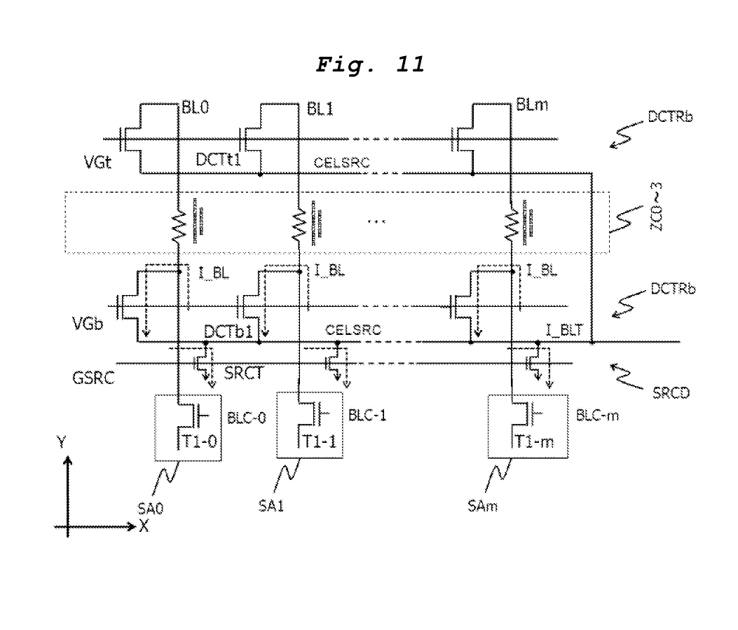

Thus, as shown in FIG. 10, the set value (trimming voltage) of the clamp voltage BLC is decided after certain device fabrication steps. FIG. 10 shows one example of a flow chart that decides the set value of the clamp voltage BLC. The adjustment of the set value of the clamp voltage BLC can be carried out, for example, during the die sort test before product shipment. Also, after product shipment, adjusting the set value can be carried out on the customer (end-user) end. Below, a case in which the set value of the clamp voltage BLC is adjusted at the time of the die sort test is described as one example.

The die sort test is executed with, for example, an external tester or a test execution circuit that is arranged in the NAND-type flash memory. Henceforth, external testers and internal test circuits shall be collectively called “tester.” In a first step (step ST1), in the case that an initial voltage Vblc is applied as the clamp voltage BLC that is applied to the gate electrode of the transistor T1, the first trimming voltage Vgbtun that is applied to the wire VGb at the time that the determination current is applied to the common source line CELSRC is decided.

First, the tester controls the control circuit 5 and turns the transistors T1, T4, and T12 of each of the sense amplifiers SA ON. Here, the clamp voltages BLC0 to BLCm that are applied to the gate electrode of the transistor T1 are made the initial voltage Vblc (a voltage that is typically around 1V to 2V higher than the set potential of the common source line CELSRC). As a result, the bit lines BL0 to BLm are charged.

The tester controls the control circuit 5, and the gate electrode (control line) of the discharge transistor DCTb applies the initial voltage Vgbt0 (a voltage that is around 1 V to 2 V higher than the set potential of the common source line CELSRC) as the initial value of the voltage Vgbt to the wire VGb (step S1-1). At this time, the tester controls the control circuit 5 and, for example, applies 0 V to the wire VGt and turns the discharge transistors DCTt0-m OFF. Also, the tester controls the control circuit 5 and applies the voltage VSRC (typically around 1 to 2 V) to the wire GSRC.

Here, the voltage control of the wire GSRC can, for example, be carried out by the control circuit shown in FIG. 13. FIG. 13 depicts one example of the driver control circuit of the source line driver SRCD. The driver control circuit includes one comparator H1, a transistor HP1, and a current source D1. The transistor HP1 is, for example, a p-type MOS transistor. The potential of the common source line CELSRC and the reference potential VREF_SRC are input into the comparator H1. The output of the comparator H1 is connected to the gate electrode (control line) of the transistor HP1. One end of the transistor HP1 is connected to the power-supply voltage, and the other end is connected to the node N1. The current source D1 is positioned between the node N1 and the ground terminal. The node N1 is connected to the wire GSRC.

The driver control circuit is a so-called feedback circuit. In the case that the potential of the common source line is higher than the reference potential VREF_SRC, the comparator outputs an L level. As a result, the current that is applied to the transistor HP1 increases, and the potential of the node N1 increases. Consequently, the potential of the wire GSRC increases, the current that is applied to the source driver transistor SRCT increases, and the potential of the common source line CELSRC decreases. On the other hand, in the case that the potential of the common source line is lower than the reference potential VREF_SRC, the comparator outputs an H level. As a result, the current that is applied to the transistor HP1 decreases, and the potential of the node N1 decreases due to the current source D1. Consequently, the potential of the wire GSRC decreases, the current that is applied to the source driver transistor SRCT decreases, and the potential of the common source line CELSRC increases. With these operations, the potential of the common source line CELSRC is controlled to be nearly the same potential as the reference potential VREF_SRC.

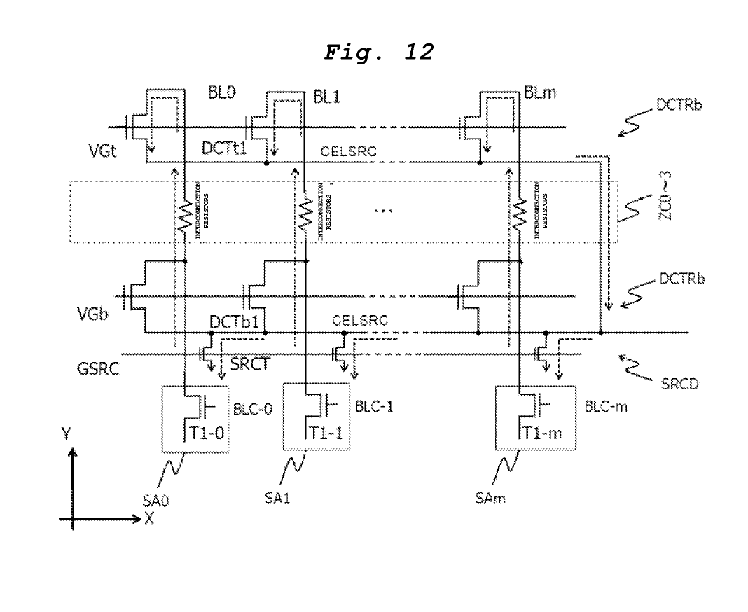

One example of the current path of the first step (step ST1) is shown in FIG. 11. For the sake of convenience, only the transistor T1 is shown in the sense amplifier SA in FIG. 11. Also, the memory cell array 1 is shown in a form that combines the zones ZC0 to ZC3. Zones ZC0 to ZC3 may be large (for example, around 10 mm), and the bit lines BL0 to BLm are, for the most part, parts that pass through the zones ZC0 to ZC3. That is, the interconnection resistance of the bit lines BL0 to BLm, for the most part, exists in the zones ZC0 to ZC3. Here, to make it clear that the bit lines BL0 to BLm include interconnection resistance, they are expressed using resistors, but specific resistor elements need not generally be included in the bit line conduction pathways.

A bit line current I_BL is flowed to each of the bit lines BL0 to BLm. Each of the bit line currents I_BL run from each of the bit lines BL0 to BLm to the common source line CELSRC via the discharge transistors DCTb0 to DCTbm. Here, one page worth (for example 2¹⁰) of bit lines BL0 to BLm are arranged. Therefore, the current that is applied to the common source line CELSRC is the sum of the currents that are applied to the bit lines BL0 to BLm. Here, the current that is applied to the common source line CELSRC shall be the bit line total current I_BLT.

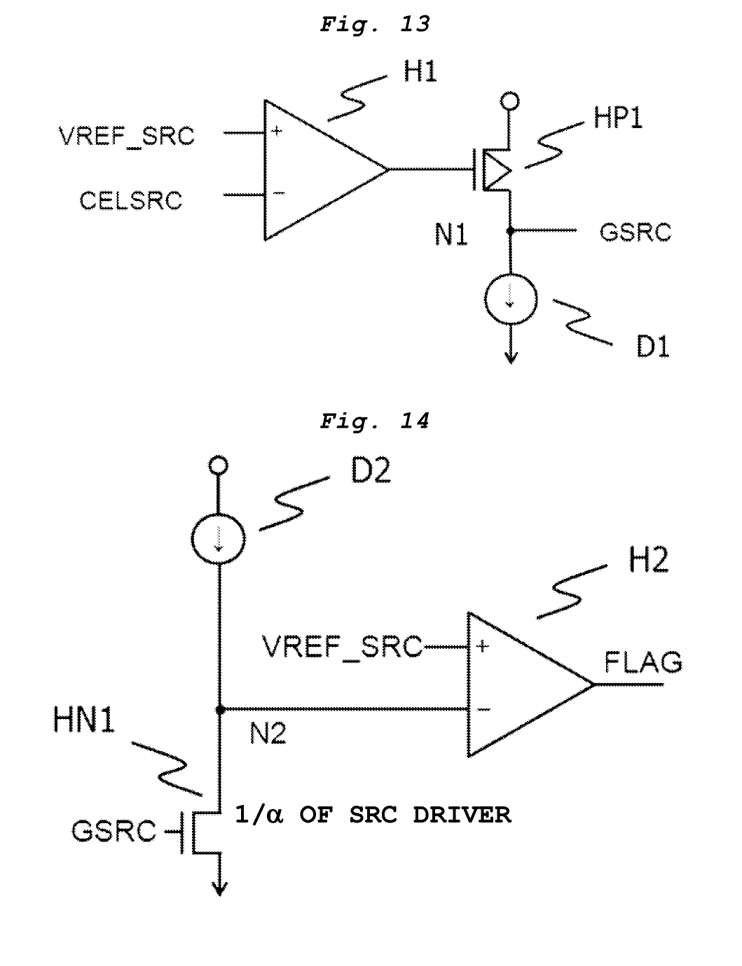

The bit line total current I_BLT is applied to the ground voltage via the source driver transistor SRCT. Here, the bit line total current I_BLT is detected by the bit line current detection circuit shown in FIG. 14.

FIG. 14 depicts one example of the bit line current detection circuit. The detection circuit includes one comparator H2, a transistor HN1, and a current source D2. The transistor HN1 is, for example, an n-type MOS transistor. The potential of the node N2 and the reference potential VREF_SRC are input into the comparator H2. The output of the comparator H2 is, for example, connected to the control circuit 5. The current source D2 is positioned between the node N2 and the power-supply voltage. One end of the transistor HN1 is connected to the node N2, and the other end is connected to the ground voltage. The gate electrode (control line) of the transistor HN1 is connected to the wire GSRC.

Here, the gate width of the transistor HN1 is 1/a times the value of the sum of the gate widths of the multiple source driver transistors SRCT. Thus, the gate width of the transistor HN1 can be made nearly equal to the gate width of the source driver transistor SRCT. For example, in the case that an a number of source driver transistors SRCT with the same shape as the transistor HN1 is arranged, one transistor HN1 should be arranged in the bit line current detection circuit.

Furthermore, the current source D2 is a current source that can apply a current that is 1/α times the determination current multiplied by number of bit lines. Here, the determination current is typically around 20 nA to 80 nA. The gate electrode of the transistor HN1 can be shared with the gate electrode of the source driver transistor SRCT. Thus, 1/α times the bit line total current I_BLT is applied to the transistor HN1. That is, if 1/α of the bit line total current I_BLT becomes greater than the determination current times the number of BL/α, or in other words, if the mean value of the bit line current I_BL becomes greater than the determination current, the potential of the node N2 becomes less than the VREF_SRC, and the output FLAG becomes an H level due to the comparator H2.

Next, the control circuit 5 checks the level of the output FLAG of the comparator H2 (step ST1-2). Here, in the case that the output FLAG is an L level, the control circuit 5 raises the voltage Vgbt that is applied to the wire VGb from the initial voltage Vgbt0 by increments of ΔVg (step ST1-3). The control circuit 5 goes back to step ST1-2 again and checks the level of the output FLAG of the comparator H2. The control circuit 5 makes the voltage Vgbt the first trimming voltage Vgbtun (step ST1-4) when the output FLAG becomes an H level. That is, until the output FLAG becomes an H level, the voltage that is applied to the wire VGb is raised in increments of ΔVg to determine the voltage that is required when the determination current is applied to the common source line CELSRC.

Next, in the second step (step ST2), in the case that the first trimming voltage Vgbtun is applied to the gate electrode (wire VGt) of the discharge transistor DCTt, the second trimming voltage VDACt that is applied to the gate electrode of the transistor T1 at the time that the determination current is applied to the common source line CELSRC is determined. The descriptions for the parts that are the same as those in the first step (step ST1) have been omitted.

First, the tester controls the control circuit 5 and turns ON the transistors T1, T4, and T12 of each of the sense amplifiers SA. Here, the clamp voltages BLC0 to BLCm that are applied to the gate electrode of the transistor T1 are made the initial voltage Vblc (steps ST2-1). As a result, the bit lines BL0 to BLm are charged.

The tester controls the control circuit 5 and the gate electrode (control line) of the discharge transistor DCTt applies the first trimming voltage Vgbtun to the wire VGt (step ST2-1). At this time, the tester controls the control circuit 5 and, for example, applies 0V to the wire VGb, and turns OFF the discharge transistors DCTb0 to DCTbm. Also, the tester controls the control circuit 5 and applies the voltage VSRC (typically around 1 to 2 V) to the wire GSRC.

One example of the current path of the second step (ST2) is shown in FIG. 12. The bit line current I_BL is applied to each of the bit lines BL0 to BLm. Each of the bit line currents I_BL run from each of the bit lines BL0 to BLm to the common source line CELSRC via the discharge transistors DCTt0 to DCTtm. Here, unlike the first step (step ST1), the bit line current I_BL is also applied to the parts of the bit line BL in the zones ZC0 to ZC3 with a high interconnection resistance. That is, in the initial stage of the second step, the bit line current I_BL is smaller than that of the first step. Similarly, in the initial stage of the second step (step ST2), the bit line total current I_BLT that is applied to the common source line CELSRC is smaller than the bit line total current of the first step (step ST1).

Here, the bit line total current I_BLT is applied to the ground voltage via the source driver transistor SRCT. The bit line total current I_BLT is detected by the bit line current detection circuit shown in FIG. 14.

Next, the control circuit 5 checks the level of the output FLAG of the comparator H2 shown in FIG. 14 (step ST2-2). Here, if the output FLAG is an L level, the control circuit 5 raises the clamp voltage BLC that is applied to the gate electrode of the transistor T1 by ΔVgd (step ST2-3). The control circuit 5 goes back to step ST2-2 again and checks the level of the output FLAG of the comparator H2. On the other hand, the control circuit 5 makes the clamp voltage BLC when the output FLAG becomes an H level to the second trimming voltage VDACt (step ST2-4). That is, until the output FLAG becomes an H level, the clamp voltage BLC that is applied to the gate electrode of the transistor T1 is raised from the initial voltage Vblc in increments of ΔVgd to determine the second trimming voltage VDACt to be applied at the time that the determination current×number of bit lines is applied to the common source line CELSRC.

Here, the threshold voltage of the transistor T1 shall be “Vth,” the difference of the second trimming voltage VDACt and the initial voltage Vblc shall be “DACtu,” and the interconnection resistance of the bit line BL shown in FIGS. 11 and 12 shall be R_BL. Also, the drain of the discharge transistors DCTb and DCTt shall be the diffusion layer that is on the side that is connected to the bit line BL.

The drain voltage of the discharge transistor DCTb in the first step becomes the (1) initial voltage Vblc−Vth.

On the other hand, the drain voltage of the discharge transistor DCTt in the second step becomes the (2) initial voltage Vblc+DACtu−Vth−R_BL×I_BL. Here, in (1) and (2), the current that is applied to the common source line CELSRC is the determination current. That is, the currents that are applied to the bit line in the first step and the second step are the same. In other words, the second trimming voltage VDACt is determined so that the voltage of (1) and (2) will be equal. Thus, DACtu=R_BL×I_BL, and the clamp voltage BLC is being raised by DACtu the amount of potential drop of the bit line.

Using this result, in the third step (ST3), the clamp voltage BLC that is appropriate for each zone ZC is determined. The tester calculates the difference between the second trimming voltage VDACt and the initial voltage Vblc and derives the third trimming voltage DACtu. The tester accounts for the number of the zones ZC and calculates the fourth trimming voltage DACtum. In the case that the number of zones ZC is m (m is a natural number greater than or equal to 2), the fourth trimming voltage DACtum becomes the third trimming voltage DACtu/(m−1).

Next, in the fourth step (ST4), the tester stores the fourth trimming voltage DACtum to the ROM region RO, etc.

### (Effects)

The clamp voltage BLC can be controlled using the trimming voltage that is most suited for each chip of each of the NAND-type flash memory. As a result, read operations, etc., can be carried out using the clamp voltage BLC that is most suited from the memory cell MC that is positioned in each of the zones ZC. For example, in the case that the interconnection resistance of the bit lines differs per each chip of the NAND-type flash memory due to variability in fabrication, the trimming voltage that is most suited for each chip can be determined. As a result, a NAND-type flash memory with high reliability can be provided.

Also, the determination of the trimming voltage is done not by using one bit line but by using multiple bit lines. That is, the trimming voltage is determined per page. As a result, the resistance change due to variability in the fabrication of each bit line BL can be averaged out. Also, the most appropriate trimming voltage can be calculated.

### Second Embodiment

In the first embodiment, the trimming voltage is determined using the discharge transistors DCTb and DCTt. On the other hand, in the second embodiment, the trimming voltage is determined using either the select transistor SS or SD. Meanwhile, the descriptions for the configurations and operations that are the same as those described in the first embodiment have been omitted.

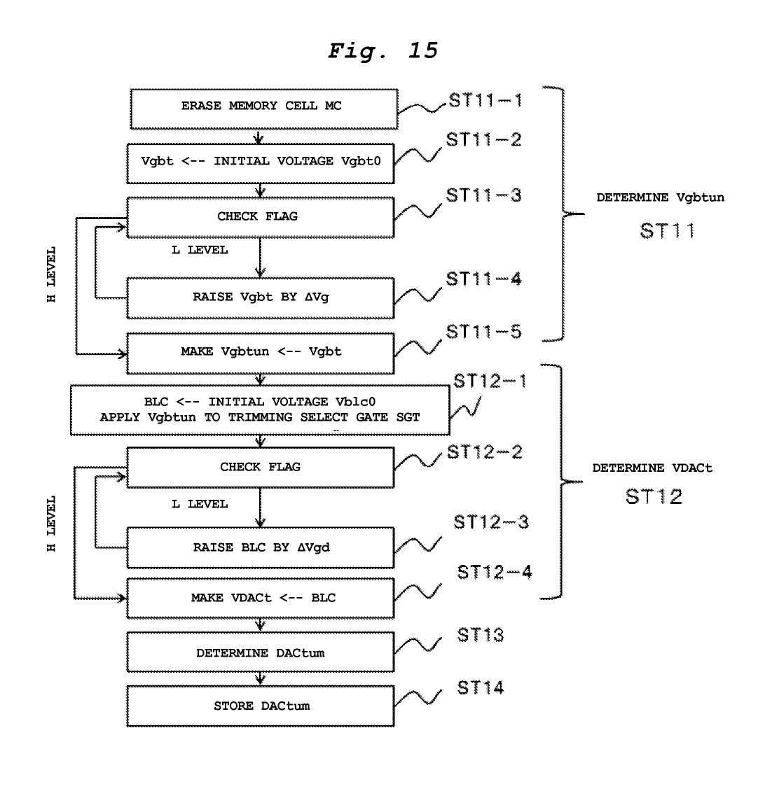

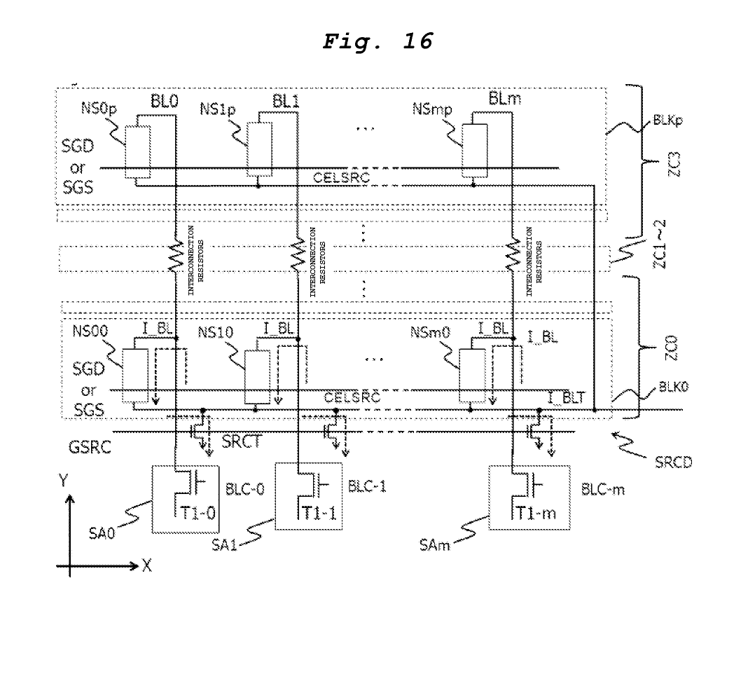

FIG. 15 shows one example of the flowchart that decides the set value of the clamp voltage BLC (trimming voltage) in the second embodiment. Also, for the bit line current detection circuit and the driver control circuit for the source line driver SRCD, the same ones as those for the first embodiment can be used.

First, in the Y-direction, the memory cell MC of the block BLK0 that is closest to the sense amplifier circuit group SAC of the zone ZC0 is kept in an erase state. Similarly, in the Y-direction, the memory cell MC of the block BLKp that is farthest from the sense amplifier circuit group SAC of the zone ZC3 is kept in an erase state (step ST11-1). Meanwhile, for example, in the case that the memory cell MC is put in an erase state in the previous die sort test, the step ST11-1 can be omitted.

Next, the bit lines BL0 to BLm are charged, as with the first embodiment. The tester controls the control circuit 5 so that the initial voltage Vgbt0 is applied to the select gate SGD or the select gate SGS of the block BLk0 as the initial value of the voltage Vgbt (step ST11-2). Here, the select gate to which the voltage Vgbt is applied shall be called the trimming select gate SGT.

Meanwhile, the select gate of the block BLK0 to which the voltage Vgbt is not applied shall be applied with the voltage Vson (typically around 4 to 6V) that will turn ON the select gate transistors SS and SD. The select gate lines SGS and SGD besides those of the block BLK0 are applied with the voltage Vsoff (Vsoff<Vson) that turns OFF the select gate transistors SS and SD. Voltage Vsoff is, for example, 0V. Also, a voltage to turn the memory cell MC ON is applied to the word line WL of the block BLK0. Additionally, the tester controls the control circuit 5 and applies the voltage VSRC to the wire GSRC.

In this way, by making the memory cell MC of the blocks BLK0 and BLKp the erase state across the board, the memory cell MC is written per each page, and it is not necessary to adjust the threshold voltage of the memory cell MC. As a result, the determination of the trimming voltage can be done quickly.

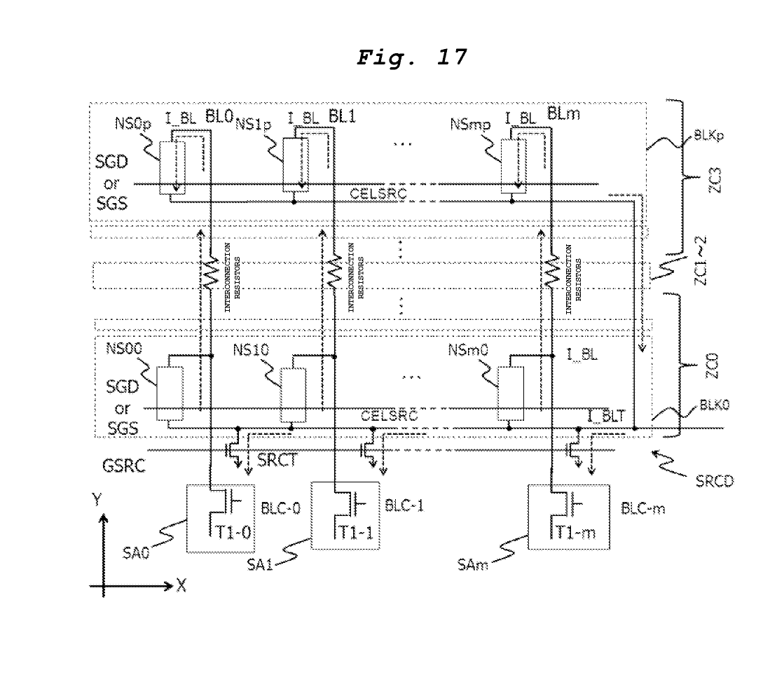

Here, one example of the current path of the first step (step ST11) is shown in FIG. 16. To each of the bit lines BL0 to BLm is applied a bit line current I_BL. Each of the bit line currents I_BL run from each of the bit lines BL0 to BLm to the common source line CELSRC via the NAND strings NS00-NSm0 of the block BKL0. Here, one page worth (for example, 2¹⁰) of bit lines BL0 to BLm are arranged. Therefore, the current that is applied to the common source line CELSRC is the sum of the currents that are applied to the bit lines BL0 to BLm. Here, the current that is applied to the common source line CELSRC shall be the bit line total current I_BLT.

The bit line total current I_BLT is applied to the ground terminal via the source driver transistor SRCT. Here, the bit line total current I_BLT is detected by the bit line current detection circuit shown in FIG. 14.

The control circuit 5 checks the level of the output FLAG of the comparator H2 (step ST11-3). Here, if the output FLAG is an L level, the control circuit 5 raises the voltage that is applied to the trimming select gate SGT by ΔVgd (step ST11-4). The control circuit 5 goes back to step ST11-3 again and checks the level of the output FLAG of the comparator H2. On the other hand, the control circuit 5 makes the voltage Vgbt when the output FLAG becomes an H level to the first trimming voltage Vgbtun (step ST11-5). That is, until the output FLAG becomes an H level, the voltage Vgbt that is applied to the trimming select gate SGT is raised from the initial voltage Vgbt0 in increments of ΔVg and determines the first trimming voltage Vgbtun at the time that the determination current is applied to the common source line CELSRC.

Next, in the second step (step ST12), in the case that the first trimming voltage Vgbtun is applied to the trimming select gate SGT of the block BLKp, the second trimming voltage VDACt that is applied to the gate electrode of the transistor T1 at the time that the determination current×number of bit lines is applied to the common source line CELSRC is determined.

First, the tester controls the control circuit 5 and turns ON the transistors T1, T4, and T12 of each of the sense amplifiers SA. Here, the clamp voltages BLC0 to BLCm that are applied to the gate electrode of the transistor T1 are made the initial voltage Vblc (step ST12-1). As a result, the bit lines BL0 to BLm are charged.

The tester controls the control circuit 5 and applies the first trimming voltage Vgbtun to the trimming select gate SGT of the block BLKp (step ST12-1). At this time, the tester controls the control circuit 5 and, for example, applies the voltage Vson to the select gate of the block BLKp to which the first trimming voltage Vgbtun is not applied. The select gates SGS and SGD besides those of the block BLKp are applied the voltage Vsoff. Also, a voltage to turn ON the memory cell MC is applied to the word line WL of the block BLKp.

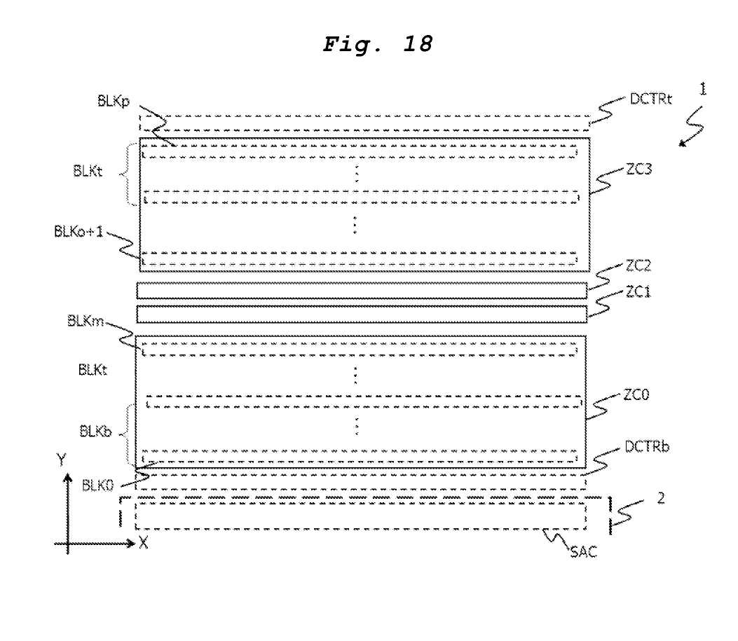

One example of the current path of the second step (step ST12) is shown in FIG. 17. A bit line current I_BL is applied to each of the bit lines BL0-m. Each of the bit line currents I_BL runs from each of the bit lines BL0 to BLm to the common source line CELSRC via the NAND strings NS0p to NSmp. Here, the current that is applied to the common source line CELSRC shall be the bit line total current I_BLT.

The control circuit 5 checks the level of the output FLAG of the comparator H2 shown in FIG. 14 (step ST12-2). Here, if the output FLAG is an L level, the control circuit 5 raises the clamp voltage BLC that is applied to the gate electrode of the transistor T1 by ΔVgd (step ST12-3). The control circuit 5 goes back to step ST12-2 again and checks the level of the output FLAG of the comparator H2. On the other hand, the control circuit 5 makes the clamp voltage BLC, when the output FLAG becomes an H level, to the second trimming voltage VDACt (step ST12-4). That is, until the output FLAG becomes an H level, the clamp voltage BLC that is applied to the gate electrode of the transistor T1 is raised from the initial voltage Vblc in increments of ΔVgd and determines the second trimming voltage VDACt at the time that the determination current×number of bit lines is applied to the common source line CELSRC.

Next, the same operations as the third step (ST13) and the fourth step (ST14) of the first embodiment are carried out.

Here, the block BLK0 that is closest to the sense amplifier circuit group SAC of the zone ZC0 is used, but any block within several tens of blocks (for example, any of the BLK1, BLK2, . . . BLK 19) can be used without problems. Similarly, instead of the block BLKp that is farthest from the sense amplifier circuit group SAC of the zone ZC3, any block within several tens of blocks (for example, any of BLKp-1, BLKp-2, . . . BLKp-19) can be used without problems.

### (Effects)

In the second embodiment, the optimal trimming voltage of the clamp voltage BLC is determined using the NAND string NS. That is, the trimming voltage of the clamp voltage BLC that is optimal in a state that is close to the state of actual operation is determined. As a result, a NAND-type flash memory with high reliability can be provided.

Also, the determination of the trimming voltage is done not by using one bit line but by using multiple bit lines. That is, the trimming voltage is determined per page. As a result, the resistance change due to variability in the fabrication of each bit line BL can be averaged out. Also, the most appropriate trimming voltage can be calculated.

### Variant Example of Second Embodiment

In the second embodiment, the trimming voltage is determined using the block BLK0 that is closest to, and the block BLKp that is the farthest from, the sense amplifier circuit group SAC. Here, in the variant example of the second embodiment, the trimming voltage is determined using multiple blocks BLK. Meanwhile, the descriptions for the configurations that are the same as the first embodiment and the second embodiment have been omitted.

FIG. 18 shows one example of the block BLK that is used for trimming in the variant example of the second embodiment. For example, as shown in FIG. 18, in the Y-direction, of the blocks BLK in the zone ZC0, the a-number (a is a natural number greater than or equal to 2) of blocks closest to the sense amplifier circuit group SAC shall be the trimming block group BLKb. Similarly, in the Y-direction, of the blocks BLK in the zone ZC3, the a-number (a is a natural number greater than or equal to 2) of blocks furthest from the sense amplifier circuit group SAC shall be the trimming block group BLKt.

The flow chart that determines the set value of the clamp voltage BLC in the variant example of the second embodiment is the same as in the second embodiment, and so it shall be described using FIG. 15.

First, the trimming block group BLKb is kept in an erase state. Similarly, the trimming block group BLKt is kept in an erase state (step ST11-1). In the case that the memory cells MC are put in an erase state in the previous die sort test, the step ST11-1 can be omitted.

Next, the bit lines BL0 to BLm are charged, as in the second embodiment. The tester controls the control circuit 5 so that the initial voltage Vgbt0 is applied to the trimming select gate SGT of the trimming block group BLKb as the initial value of the voltage Vgbt (step ST11-2).

Meanwhile, the select gate of the trimming block group BLKb to which the voltage Vgbt is not applied shall be applied with the voltage Vson that will turn ON the select gate transistors SS and SD. The select gates SGS and SGD besides those of the trimming block group BLKb are applied with the voltage Vsoff. Also, a voltage to turn ON the memory cell MC is applied to the word line WL of the block BLKb. Additionally, the tester controls the control circuit 5 and applies the voltage VSRC to the wire GSRC.

The operation of the first step ST11 thereafter is the same as in the second embodiment.

Next, in the second step (step ST12), in the case that the first trimming voltage Vgbtun is applied to the trimming select gate SGT of the trimming block group BLKt, the second trimming voltage VDACt that is applied to the gate electrode of the transistor T1 at the time that the determination current is applied to the common source line CELSRC is decided.

First, the tester controls the control circuit 5 and turns ON the transistors T1, T4, and T12 of each of the sense amplifier circuits SA. Here, the clamp voltages BLC0 to BLCm that are applied to the gate electrode of the transistor T1 are made the initial voltage Vblc. As a result, the bit lines BL0 to BLm are charged. The operation thereafter is the same as in the second embodiment.

### (Effects)

By increasing the number of the NAND strings NS that are used to determine the trimming voltage, the effects of variability of fabrication can be minimized. That is, the fabrication variability of the NAND string NS in the block BLK is averaged out and the trimming voltage can be determined. As a result, a NAND-type flash memory with high reliability can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A non-volatile semiconductor storage device, comprising:
a plurality of memory blocks, each including a plurality of memory strings;
a bit line extending in a first direction and connected to an end of a memory string in each memory block;
a first discharge transistor connected to the bit line proximate to a first end of the bit line;
a second discharge transistor connected to the bit line proximate to a second end of the bit line that is separated from the first end in the first direction by at least one of the memory blocks;
a sense amplifier connected to the bit line at the second end, the sense amplifier configured to provide a sensing voltage to the bit line;
a control circuit configured to control the sensing voltage by supplying a trimming voltage to a gate of a first transistor in the sense amplifier, wherein
the control circuit is configured to adjust the trimming voltage based on a distance of a selected memory block from the sense amplifier.

2. The non-volatile semiconductor storage device of claim 1, wherein the plurality of memory blocks is divided into a plurality of zones based on distance from the sense amplifier.

3. The non-volatile semiconductor storage device of claim 1, wherein no memory blocks are between the second discharge transistor and the sense amplifier.

4. The non-volatile semiconductor storage device of claim 1, wherein there is at least one memory block between the second discharge transistor and the sense amplifier.

5. The non-volatile semiconductor storage device of claim 1, wherein the first discharge transistor is farther from the sense amplifier or nearer to the sense amplifier than at least one memory block.

6. The non-volatile semiconductor storage device of claim 1, further comprising:
a common source line connected to a terminal of the first discharge transistor and a terminal of the second discharge transistor such that when either the first or second discharge transistor is in a conductive state a charge on the bit line discharges, wherein
the control circuit is further configured to set the trimming voltage by selecting a value of the trimming voltage that makes a current through the first discharge transistor to the common source line approximately match a current through the second discharge transistor to the common source line when the sensing voltage is applied to the bit line.

7. The non-volatile semiconductor storage device of claim 6, wherein each memory string includes a plurality of memory cells connected in series with a first selection transistor connected to a first end of the memory string and a second selection transistor connected to a second end of the memory string;
a first selection transistor of a memory string in a first memory block is the first discharge transistor; and
a second selection transistor of a memory string in a second memory block that is closer to the sense amplifier in the first direction than the first memory block is the second discharge transistor.

8. The non-volatile semiconductor storage device of claim 6, further comprising:
a bit line current detection circuit configured to measure the current in the common source line.

9. The non-volatile semiconductor storage device of claim of claim 8, wherein the current detection circuit includes a comparator configured to compare a reference voltage to a voltage across a transistor connected to a ground potential.

10. The non-volatile semiconductor storage device of claim 6, further comprising:
a source line driver circuit including a comparator configured to compare a voltage of the common source line to a reference voltage and output a control signal based on the comparison.

11. A method for controlling a non-volatile semiconductor storage device having a plurality of memory blocks, each including a plurality of memory strings, a bit line extending in a first direction and connected to an end of a memory string in each memory block; a first discharge transistor connected to the bit line proximate to a first end of the bit line; a second discharge transistor connected to the bit line proximate to a second end of the bit line that is separated from the first end in the first direction by two or more memory blocks; a sense amplifier connected to the bit line at the second end, the sense amplifier configured to provide a sensing voltage to the bit line, the method comprising:
applying a first sensing voltage to the bit line while the first discharge transistor is in a conductive state, and measuring a first current level in a common source line connected to the first discharge transistor;
applying the first sensing voltage to the bit line while the second discharge transistor is in a conductive state, and measuring a second current level in the common source line connected to the second discharge transistor;
comparing the first current level and the second current level; and
determining a trimming voltage that when supplied to the sense amplifier provides a second sensing voltage that when applied to the bit line when the first discharge transistor is in a conductive state results in a third current level in the common source line that is approximately equal to the second current level.

12. The method of claim 11, wherein the step of determining a trimming voltage includes changing the trimming voltage by fixed increments until the third current level is approximately equal to the second current level.

13. The method of claim 11, further comprising:
storing a value of the trimming voltage that when supplied to the sense amplifier provides a second sensing voltage that when applied to the bit line when the first discharge transistor is in a conductive state results a third current level in the common source line that is approximately equal to the second current level.

14. The method of claim 11, wherein the first discharge transistor is a first selection transistor in a memory string in a first memory block, and the second discharge transistor is a second selection transistor in a memory string in a second memory block, the second memory block closer to the sense amplifier than the first memory block.

15. The method of claim 11, further comprising dividing the plurality of memory blocks into a plurality of zones based on a distance in the first direction from the sense amplifier, each zone containing at least one memory block.

16. The method of claim 15, wherein trimming voltages are separately established for each zone.

17. A method of die sorting testing a non-volatile semiconductor storage device having a plurality of memory blocks, each including a plurality of memory strings, a bit line extending in a first direction and connected to an end of a memory string in each memory block; a first discharge transistor connected to the bit line proximate to a first end of the bit line; a second discharge transistor connected to the bit line proximate to a second end of the bit line that is separated from the first end in the first direction by two or more memory blocks; a sense amplifier connected to the bit line at the second end, the sense amplifier configured to provide a sensing voltage to the bit line, the method comprising:
applying a first sensing voltage to the bit line while the first discharge transistor is in a conductive state, and measuring a first current level in a common source line connected to the first discharge transistor;
applying the first sensing voltage to the bit line while the second discharge transistor is in a conductive state, and measuring a second current level in the common source line connected to the second discharge transistor;
comparing the first current level and the second current level;
determining a trimming voltage that when supplied to the sense amplifier provides a second sensing voltage that when applied to the bit line when the first discharge transistor is in a conductive state results in a third current level in the common source line that is approximately equal to the second current level; and
storing a value of the trimming voltage that when supplied to the sense amplifier provides a second sensing voltage that when applied to the bit line when the first discharge transistor is in a conductive state results a third current level in the common source line that is approximately equal to the second current level.

18. The method of claim 17, wherein the memory blocks of the non-volatile semiconductor memory device are divided into zones based on a distance from the sense amplifier, and a trimming voltage is established for each zone.

19. The method of claim 17, wherein the value of the trimming voltage is stored in a read-only memory portion of the non-volatile semiconductor memory device.

20. The method of claim 17, wherein the step of determining a trimming voltage includes changing the trimming voltage by fixed increments until the third current level is approximately equal to the second current level.
